(19) United States
(12) Patent Application Publication
(10) Pub. No.: US 2014/0153192 A1
(43) Pub. Date: Jun. 5, 2014

(54) MODULE CAGE WITH INTEGRATED EMI ASPECT

(71) Applicant: Molex Incorporated, Lisle, IL (US)

(72) Inventors: Jay H. Neer, Boca Raton, FL (US); Harold Keith LANG, Cary, IL (US)

(73) Assignee: Molex Incorporated, Lisle, IL (US)

(21) Appl. No.: 14/089,979

(22) Filed: Nov. 26, 2013

Related U.S. Application Data
(60) Provisional application No. 61/733,624, filed on Dec. 5, 2012.

(51) Int. Cl. H05K 7/20

(52) U.S. Cl. CPC H05K 7/20418
USPC 361/704

(57) ABSTRACT

A receptacle assembly with improved EMI leakage reduction is described. The assembly includes a base in the form of either a guide frame or a shielding cage that received an electronic module or mating connector therein. A heat sink is provided to dissipate heat generated during operation of the connector or module and the heat sink has a portion that extends into the interior of the receptacle through an opening in the top wall thereof. The heat sink has a peripheral rim that is aligned in opposition to a rim of the top wall of the receptacle. A series of individual contact members are disposed in the top wall and arranged in a pattern extending around the opening to provide a plurality of points of electrical grounding contact between the heat sink and the receptacle.

### REFERENCE TO RELATED APPLICATIONS

The Present Disclosure claims priority to prior-filed U.S. Provisional Patent Application No. 61/733,624, entitled “Module Cage With Integrated EMI Aspect,” filed on 5 Dec. 2012 with the United States Patent And Trademark Office. The content of the aforementioned Patent Application is incorporated in its entirety herein.

### BACKGROUND OF THE PRESENT DISCLOSURE

The Present Disclosure relates, generally, to shielding cages, and, more particularly, to cages used in association with heat sinks and the like.

The use of pluggable modules in the electronics field is growing. Pluggable modules may be used in association with ordinary, copper-based electrical systems, or with fiber-optic systems. However, pluggable modules used in high-speed systems generate significant heat. This heat must be carried away from the module in order to keep its operating temperature down to a level for which it was designed. Pluggable modules are typically inserted into a shielding cage that shields the connection between an edge card protruding from the insertion end of a module and a receptacle connector mounted to a circuit board. The shielding cage is mounted to the circuit board, and forms a hollow space that envelops the receptacle connector. In order to remove the heat generated during operation, the industry has adopted the use of heat sinks as a solution to this heat problem. Once such heat sink is described and shown in U.S. Pat. No. 6,816,376, assigned to Tyco Electronics, wherein the shielding cage has an opening formed in its top wall, or roof (the content of this Patent is incorporated by reference herein). This opening permits access to the interior of the shielding cage and to the pluggable module. A heat sink is typically formed of metal, and may have a base that extends into the interior of the shielding cage and into contact with the top of the pluggable module. The heat sink is typically designed so that its base touches the top surface of the module and a rim that extends around the heat sink base sits on and contacts the shielding cage. A hold down clip may be provided to maintain the heat sink in contact with the module.

One problem that occurs with such a structure is that either the module or the shielding cage, or both, may be manufactured out of dimension. If so, the heat sink rim separates, either partially or wholly, from contact with the shielding cage, creating a gap. Depending upon the severity of the misalignment, this gap may extend around the entire extent of the opening in the upper surface of the cage. Where the gap occurs between the heat sink and the cage, it defines a portal for the emanation of electromagnetic interference (“EMI”). Designers strive to achieve the lowest possible leakage of EMI from any cage, as EMI is prone to interfere with the transmission of signals through the module and other electronic devices in proximity to the cage and module. In view of such problems, it is therefore desirable to provide a shielding cage that has an EMI reduction solution associated with it (additionally, such may be required by governmental entities, such as the FCC, which assures that the final system does not create EMI when installed).

### SUMMARY OF THE PRESENT DISCLOSURE

Accordingly, there is provided an improved shielding cage that receives not only a pluggable module therein but also an exterior heat sink member that extends into the cage and into contact with the module. The cage includes a plurality of sides, or walls, that cooperatively define a hollow interior intended to house a receptacle connector mounted to a circuit board. The cage preferably includes mounting members in the form of legs or compliant pins and the like which permit it to be mounted to a circuit board over the receptacle connector. In order to facilitate the insertion of a pluggable module into the cage and into engagement with the receptacle connector, the cage has an opening disposed at one end thereof sized to receive a pluggable module therein.

Furthermore, the cage has an opening disposed in a primary surface thereof extending along the top side or wall of the cage; this opening accommodates a heat sink member. The heat sink member has a base portion that extends into the cage interior, intended to contact the top of a module therein, and a rim surrounding the base portion. This peripheral rim has a bottom surface that is preferably flat, intended to contact opposing portions of a primary surface of the cage, one that at least partially defines a top wall, or surface thereof.

The cage is provided with a plurality of resilient contact members that may take the form of spring arms punched, or otherwise formed, in the primary surface of the cage, and which are arranged in a peripheral pattern extending around the heat sink opening. These contacting members are formed as individual spring arms, that are elastic in nature and which extend away from the primary surface in a direction toward (or in opposition to) the heat sink peripheral rim. The contacting members define a plurality of contact points, which provide an integrated EMI prevention aspect to the shielding cage.

The contacting members may take the form of simple elongated, cantilevered arms, or formed with curved free ends or other shapes as may be deemed suitable for establishing a plurality of contact points around the perimeter of the heat sink opening. Such a structure eliminates the need for a separately formed gasket and dispenses with the labor required to align and apply such a gasket to the cage during assembly, and thus provides an economic saving to the manufacturer and user of the shielding cage.

These and other objects, features and advantages of the Present Disclosure will be clearly understood through a consideration of the following detailed description.

### BRIEF DESCRIPTION OF THE FIGURES

The organization and manner of the structure and operation of the Present Disclosure, together with further objects and advantages thereof, may best be understood by reference to the following Detailed Description, taken in connection with the accompanying Figures, wherein like reference numerals identify like elements, and in which:

FIG. 1 is a perspective view of a conventional receptacle-module assembly mounted on a circuit board;

FIG. 2 is a perspective view of a receptacle assembly incorporating an integrated EMI reduction aspect in accordance with the Present Disclosure;

FIG. 3 is an enlarged detail view of a corner of the opening in the top wall of the guide frame of the assembly of FIG. 2, illustrating the arrangement of contact members thereon;

FIG. 4 is a top plan view of one of the contact members disposed on the guide frame of FIG. 2;

FIG. 5A is a side elevational view of one construction of a contact member used in accordance with the integrated EMI guide frames of the Present Disclosure;

FIG. 5B is the same view as FIG. 5A, but with the contact member free end deflected toward the shielding cage top wall under pressure of the heat sink;

FIG. 6 is a front elevational view of a shielding cage with a different integrated EMI aspect in accordance with the present disclosure, wherein the contact members depend downwardly into the shielding cage interior to contact the heat sink; and

FIG. 7 is a side elevational view of another construction of a contact member used in accordance with the integrated EMI guide frames of the present disclosure.

### DESCRIPTION OF THE PREFERRED EMBODIMENTS

While the Present Disclosure may be susceptible to embodiment in different forms, there is shown in the Figures, and will be described herein in detail, specific embodiments, with the understanding that the disclosure is to be considered an exemplification of the principles of the Present Disclosure, and is not intended to limit the Present Disclosure to that as illustrated.

In the embodiments illustrated in the Figures, representations of directions such as up, down, left, right, front and rear, used for explaining the structure and movement of the various elements of the Present Disclosure, are not absolute, but relative. These representations are appropriate when the elements are in the position shown in the Figures. If the description of the position of the elements changes, however, these representations are to be changed accordingly.

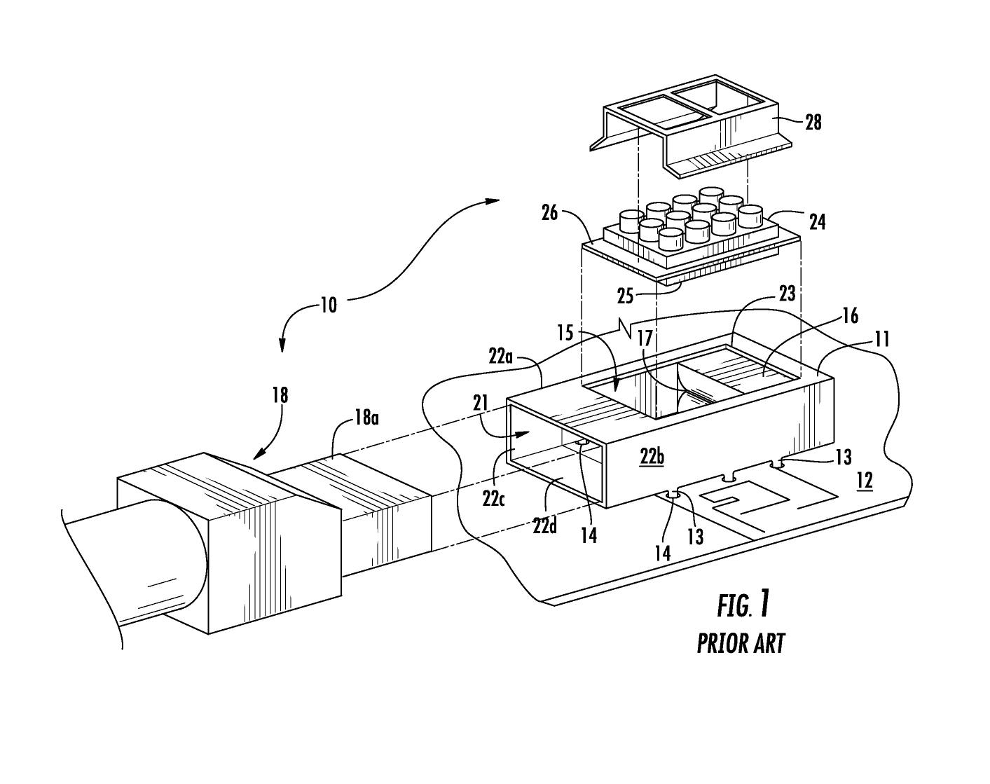

FIG. 1 illustrates a known receptacle assembly 10. The assembly 10 includes a guide frame 11 mounted to a circuit board 12 by way of a plurality of downwardly depending mounting legs 13 or the like received within holes, or vias 14, formed in the circuit board 12. The guide frame 11 has a hollow interior 15 that receives a receptacle connector 16, which, as illustrated, may include a card-receiving slot 17 that is configured to receive a projecting edge card or other similar mating blade (not shown) from a mating connector 18. The guide frame 11 is preferably formed from a conductive material and can be die-cast or stamped from sheet metal, and the mounting legs 13 thereof are connected to ground circuit on the circuit board 12.

A mating connector 18 has a conductive outer body 19 and a nose portion 20 thereof, configured to be received in the guide frame interior 15 by insertion through an entrance opening 21 defined in the front of the guide frame 11. The guide frame 11, as seen, includes a plurality of walls 22a-d, and another opening 23 is formed in one of the walls 22a that defines a top surface thereof. A heat sink member 24 is provided and includes a base portion 25 that depends downwardly and is received through the top opening 23 so that it may contact the mating connector 18 along the top surface 18a thereof, The heat sink member 24 further includes a rim 26 extending around the periphery of the base portion 25 and in opposition to the top wall 22a of the guide frame 11. A retention, or hold-down clip, 28 is typically provided to hold the heat sink member 24 in place with the guide frame 11 and in contact with the mating connector 18.

The clip 28 holds the rim 26 of the heat sink member 24 down, in contact with the top of the guide frame 11 before the heat sink member 24 is inserted into the guide frame 11. As the heat sink member 24 is installed into the guide frame 11, its leading edge, chamfered to match the chamfer on the leading edge of the guide frame 11 to form a ramp to reduce the insertion force, raises the rim up off the top of the guide frame 11, thereby creating a 360° opening or gap between the top of the cage and the bottom of the rim 25 while the heat sink member 24 is installed in its operating position. The spring fingers in the top of the guide frame 11 therefore close this 360° EMI gap by maintaining contact between the rim of the heat sink member 24 and the top of the guide frame 11. The spacing between the spring contacts must be designed to effectively block the frequency of the emissions associated with the application.

The heat sink works to dissipate heat to the atmosphere from the mating connector by making contact with the top surface of the mating connector 18. However, either the mating connector 18 or the guide frame 11 may be out of tolerance and the heat sink member 24, and particularly the rim 26 thereof, may be consequently lifted away from the guide frame 11 that overcomes the retention force applied to the heat sink by the retention clip 28, thereby creating a gap or gaps along the rim 26. EMI can easily travel out of this gap, and at high data transmission speeds, create noise and electrical interference with other circuit in the device that houses the receptacle assembly.

FIGS. 2-7 illustrate a new receptacle assembly 100 constructed in accordance with the Present Disclosure that avoids the aforementioned problems. Such an assembly 100, as illustrated, includes a guide frame 102 mounted to a circuit board 104, and which has a hollow interior space 106 configured to receive a receptacle connector (not shown) and an opposing mating connector 108, shown generally as having the shape of an electronic module. The guide frame 102 is illustrated as being a conductive shielding cage 110 preferably formed from sheet metal and having a plurality of walls 112 that cooperatively define the interior space 106. An entrance opening 114 is provided at the front of the cage 110, and the entrance is sized to permit the insertion therein of an electronic module 108. The module 108 has a projecting mating blade 116 that usually includes an edge card received within a card-receiving slot of a receptacle connector (not shown), also mounted to the circuit board 104 and enclosed within the interior space 106 of the cage 110.

The cage walls 112 include a top wall 112a, two side walls 112b, 112c, a bottom wall 112d and a rear wall 112e. A mounting collar 118 may be disposed on the cage 112 proximate to the entrance opening 114 thereof, and may include a compressible conductive gasket 120 to form an EMI seal between the cage and the bezel of the device which houses the cage and its receptacle connector. During operation, and particularly at high data transmission speeds, heat is generated and needs to be dissipated from the module to the atmosphere. This is accomplished by providing a heat sink 122 to electrically contact the module 108.

The heat sink 122 takes the form of a thermally conductive member 124, preferably solid, and having a body or base portion 125 that defines a contacting, or absorption, portion of the heat sink 122, and a dissipating portion 126 that includes a plurality of spaced-apart individual posts 127 that rise up from the base portion 125 and extend vertically above the module 108 and the cage 110. The base portion 125 is smaller in size than the dissipating portion 126, such that a rim 128 is defined that extends around the base portion 125. The cage 110 is provided with a heat sink opening 130 formed in the top wall 112a of the cage 110, and is configured to receive the heat sink base portion 125 therein so that when the module 108 is inserted into the cage 110, the top surface 109 of the module 108 will contact the bottom surface 124 of the heat sink base portion 125 and heat generated by the module will be absorbed by the heat sink 122.

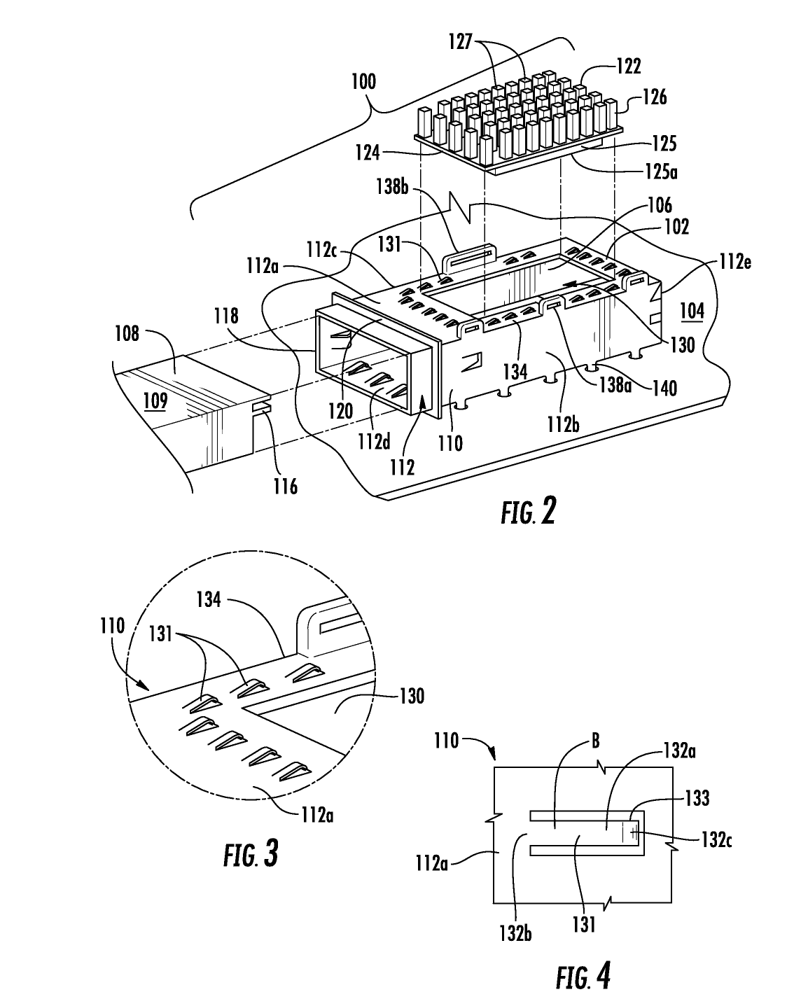

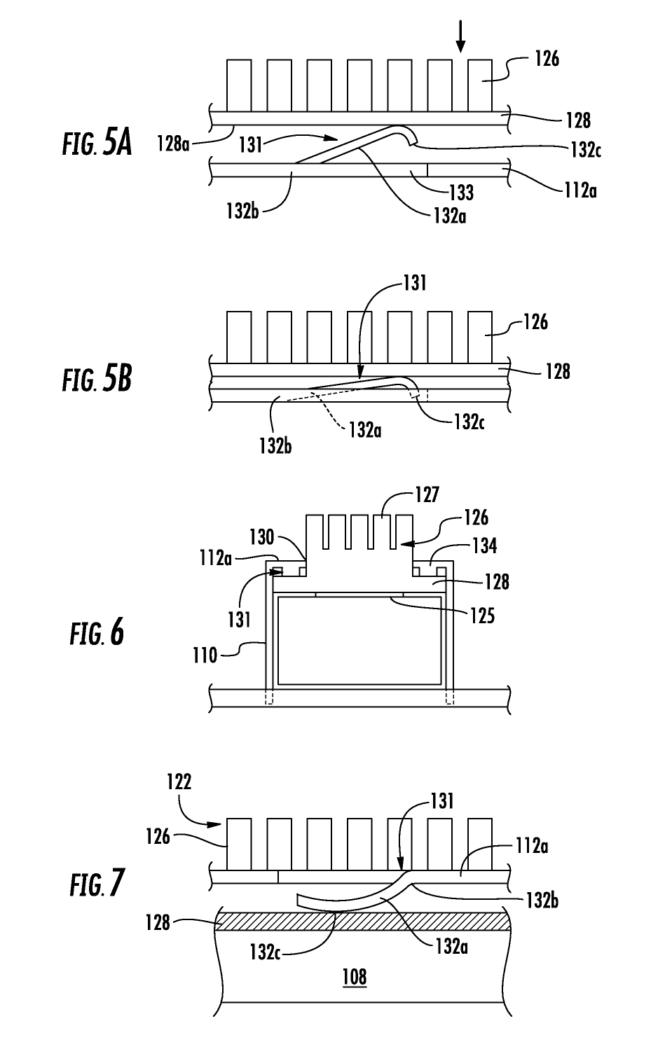

In order to prevent the separation problem discussed above from occurring and creating a gap through which EMI can pass, a plurality of conductive contact members 131 are provided on the cage 110. These contact members 131, as shown in FIGS. 2-5, are formed, such as by stamping, from the cage 110 itself. As illustrated in FIG. 4, the contact members may be easily formed by stamping a U-shaped slot 133 into the cage top wall 112a in the area that extends around the heat sink opening 130. In this fashion, the contact members 131 are formed as cantilevered contact members or arms, each of which has an elongated body portion 132a joined to the cage top wall 112a at a base portion 132b and a free end 132c that can freely deflect under pressure of the heat sink 122. The contact members 131 are thin and resilient, so that the contact members are inherently elastic in nature. In order to provide a reliable point contact, it is preferred that each contact member free end 132c be curved as shown in FIG. 5. This curvature also effectively shortens the length of the contact member to a length shorter than the length of the U-shaped slot 133 so that, if needed, the contact member free end 132c may deflect into the slot 133, as illustrated in FIG. 5B. Such a configuration may be provided by coining, although ordinary stamping will suffice. As noted, the U-shaped slot permits deflection of the contact member 131 and its free end 132c below the level of the top wall 112a of the cage 110.

As shown in FIG. 2, the contact members 131 are arranged along a flat rim portion 134 of the top wall 112a of the cage 110 that surrounds the top opening 130, to provide a plurality of points of contact between the contact member free ends and the opposing rim portion 128 of the heat sink. Preferably, the contact members 130 are arranged in a uniform spacing that surrounds the top opening, but as shown, selective contact members may be eliminated in areas where other members of the cage are in contact with the heat sink, such as the two hold down tabs 138a, 138b shown on opposite sides of the heat sink 122. These tabs 138a, 138b are crimped down onto the heat sink dissipating portion 126 after the heat sink 122 is installed, in order to hold the heat sink 122 in place on the cage 110, but also to provide points of conductive grounding contact between the cage 110 and the heat sink in the areas along the cage rim 134 where no contact members 131 are present for reducing EMI emissions. Such tabs 138a, 138b make their points contact within the non-uniform spaces in the contact member 131 pattern. These tabs are preferably positioned so that, in combination with the contact members, a uniform spacing between all of the associated contact points is affected.

By separately providing a plurality of conductive contact points along the cage rim 134 around the perimeter of the heat sink opening 130, effective EMI shielding is effected between the heat sink 122 and the cage 110. In instances where the heat sink 122 and the module 108 are out of tolerance, some contact will be made between the heat sink rim 128 and the opposing cage rim 134, and in areas where contact may not occur between these opposing members, the elongated extent of the contact members 131 will provide contact between the heat sink rim 128 and the cage rim 134 through the contact member body portions 132a. Inasmuch as the cage is connected to ground by way of its mounting legs 140, the contact members provide grounded points of contact spaced along the perimeter.

Although a non-uniform spacing of the contact members is shown in FIGS. 2-3, due to the retention tabs 138a, 138b being formed from the cage walls 112, it will be understood that in certain applications, such as where a separate retention clip is used similar to that shown in FIG. 1, a uniform spacing of the contact members 131 would be preferred. Another embodiment is shown in FIGS. 6-7, where the contact members 131 are formed from the cage top wall and depend down into the interior space 106 of the cage. In this embodiment, the heat sink base portion 125 and its surrounding rim 128 are contained within the cage and disposed underneath and in opposition to the cage top wall 112a. Contact is desired in this embodiment between the top surface of the heat sink rim 128 and the bottom surface of the cage rim 134 and hence, the contact members are stamped and formed downwardly to provide the desired electrical grounding contact.

Although the integrated EMI aspect has been explained in the context of a shield cage, it can also be used on a guide frame that has multiple components, such as a die-cast body and a sheet metal cover. In such an instance, the cover will have an opening defined therein to permit the passage of the heat sink therethrough and the cover will have a peripheral rim portion extending around the opening where the contact members can be formed. Lastly, it is envisioned that the contact members may be formed separately, as in metal strips that may be applied to the cage, such as be welding or conductive adhesives or the like.

While a preferred embodiment of the Present Disclosure is shown and described, it is envisioned that those skilled in the art may devise various modifications without departing from the spirit and scope of the foregoing Description and the appended Claims.

What is claimed is:

1. A shielding cage, the shielding cage comprising:
a plurality of walls, the walls cooperatively defining a hollow interior configured to receive a module therein, one of the walls including at least a primary wall extending in proximity and opposition to the module;
an opening, the opening being defined in the primary wall and configured to receive a portion of a heat sink therein, the primary wall including a peripheral rim extending around the opening; and
a plurality of contact members, each contact member being disposed on the primary wall along a peripheral rim thereof and extending away from the primary wall to contacting an opposing surface of the heat sink.

2. The shielding cage of claim 1, wherein each contact member is resilient.

3. The shielding cage of claim 2, wherein each contact member is cantilevered.

4. The shielding cage of claim 3, wherein each contact member has free ends that extend above the primary wall.

5. The shielding cage of claim 3, wherein each contact member has free ends that extend underneath the primary wall.

6. The shielding cage of claim 3, wherein each contact member has curved free ends.

7. The shielding cage of claim 1, wherein each contact member is separately formed as a strip disposed on the primary wall.

8. A receptacle assembly configured to receive a mating connector, the receptacle assembly comprising:
a conductive guide frame, the conductive guide frame including a primary top wall having an opening and a plurality of secondary walls, the walls cooperatively defining an interior space configured to receive the mating connector, the opening providing access to the interior space; and
a heat sink member, the heat sink member being partially received within the interior space and the opening;
wherein the guide frame further includes a plurality of conductive contact members extending away therefrom and configured to contact the heat sink member when the heat sink member is received within the opening, each contact member being arranged along the primary top wall in a pattern that surrounds the opening.

9. The receptacle assembly of claim 8, wherein each contact member is formed from the guide frame.

10. The receptacle assembly of claim 9, wherein each contact member extends from the guide frame into the interior space.

11. The receptacle assembly of claim 8, wherein each contact member extends from the guide frame toward the heat sink member.

12. The receptacle assembly of claim 8, wherein the heat sink includes a base portion, the base portion extending through the opening.

13. The receptacle assembly of claim 12, wherein the heat sink further includes a rim portion, the rim portion extending around the base portion.

14. The receptacle assembly of claim 13, wherein the rim portion contacts each contact member when the heat sink is inserted into the opening.

15. The receptacle assembly of claim 14, wherein each contact member includes free ends with curved contact portions.

16. The receptacle assembly of claim 8, wherein the guide frame further includes other contact members that contact the heat sink.

17. The receptacle assembly of claim 8, wherein the guide frame further includes a die-cast body, the die-cast body having a plurality of walls.

18. The receptacle assembly of claim 17, wherein the guide frame further includes a cover portion, the cover portion defining the top wall.

19. The receptacle assembly of claim 18, wherein the opening is oriented within the cover portion to define a rim portion extending around the opening.

20. The receptacle assembly of claim 19, wherein each contact member is arranged in a pattern in the rim portion.
